(19) United States
(12) Patent Application Publication
(10) Pub. No.: US 2010/0181675 A1
(43) Pub. Date: Jul. 22, 2010

(54) SEMICONDUCTOR PACKAGE WITH WEDGE BONDED CHIP

(75) Inventors: Dexter Reynoso, Singapore (SG); Erwin Orejola, Singapore (SG)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/355,438

(22) Filed: Jan. 16, 2009

(51) Int. Cl. H01L 23/498; H01L 21/60

(52) U.S. Cl. 257/762; 438/124; 257/E23.072; 257/E21.506

(57) ABSTRACT

A semiconductor package with wedge bonded chip. One embodiment provides a semiconductor chip, a wire bond and a metal element. The chip includes a bond pad with a copper layer. The wire bond is wedge bonded to the bond pad and ball bonded to the metal element.

### BACKGROUND

The present invention generally relates to a semiconductor package, and in one embodiment to a semiconductor package that includes a chip and a wire bond that is wedge bonded to the chip.

Semiconductor chips include bond pads that are electrically connected to external circuitry in order to function as part of an electronic system. The external circuitry is typically a lead array such as lead frame or a support substrate such as a printed circuit board. Electrical connection between the chip and the external circuitry is often achieved by wire bonding, tape automated bonding (TAB) or flip-chip bonding. For instance, with flip-chip bonding, ball grid array (BGA) packages contain an array of solder balls to mount on corresponding terminals on a printed circuit board, and land grid array (LGA) packages contain an array of metal pads that receive corresponding solder traces mounted on corresponding terminals on a printed circuit board.

Wire bonding is the most common and economical connection technique. The wires are bonded, one at a time, from the chip to external circuitry by thermocompression, thermosonic or ultrasonic processes. For instance, a wire is fed from a spool through a clamp and a capillary, a thermal source forms a wire ball on the wire, the capillary is brought down over an aluminum bond pad and exerts pressure on the wire ball, and the wire ball forms a ball bond on the bond pad using thermocompression. The capillary is then raised and moved to a lead and brought down again, and the force and heat form a wedge bond on the lead using ultrasonic vibration. After raising the capillary again, the wire is ripped from the wedge bond and the process is repeated for other bond pads and leads. There are many variations on these basic methods.

Wire bonds have been devised that include a wedge bond on a ball bond on the bond pad and a ball bond on the lead. The ball bond on the bond pad prevents the wedge bond from propagating cracks through the bond pad into an underlaying aluminum layer of the chip. However, the ball bond on the bond pad requires extra wire and entails an additional process step, which increases size, cost and manufacturing time.

Therefore, there is a need for a wire bonding process that provides a wedge bond on a chip in a reliable, efficient and cost-effective manner.

### SUMMARY

The present invention provides a semiconductor package that includes a semiconductor chip, a wire bond and a metal element. The chip includes a bond pad with a copper layer. The wire bond is wedge bonded to the bond pad and ball bonded to the metal element.

The present invention also provides a method of manufacturing a semiconductor package that includes providing a semiconductor chip that includes a bond pad with a copper layer, providing a metal element that is spaced from the chip, and then wedge bonding a wire bond to the bond pad and ball bonding the wire bond to the metal element.

These and other features and advantages of the present invention will become more apparent in view of the detailed description that follows.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a cross-sectional view of a semiconductor package in accordance with one embodiment.

FIGS. 2A-2C illustrate cross-sectional views of a method of making the semiconductor package of FIG. 1.

FIG. 3 illustrates a cross-sectional view of a semiconductor package in accordance with one embodiment.

FIG. 3A illustrates an enlarged cross-sectional view of the bond pad and wedge bond in FIG. 3.

FIGS. 4A-4D illustrate cross-sectional views of a method of making the semiconductor package of FIG. 3.

FIG. 5 illustrates a cross-sectional view of a semiconductor package in accordance with one embodiment.

FIG. 5A illustrates an enlarged cross-sectional view of the bond pad and wedge bond in FIG. 5.

FIGS. 6A-6D illustrate cross-sectional views of a method of making the semiconductor package of FIG. 5.

FIG. 7 illustrates a cross-sectional view of a semiconductor package in accordance with one embodiment.

FIG. 7A illustrates an enlarged cross-sectional view of the bond pad and wedge bond in FIG. 7.

FIGS. 8A-8D illustrate cross-sectional views of a method of making the semiconductor package of FIG. 7.

FIG. 9 illustrates a cross-sectional view of a semiconductor package in accordance with one embodiment.

FIGS. 10A-10D illustrate cross-sectional views of a method of making the semiconductor package of FIG. 9.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

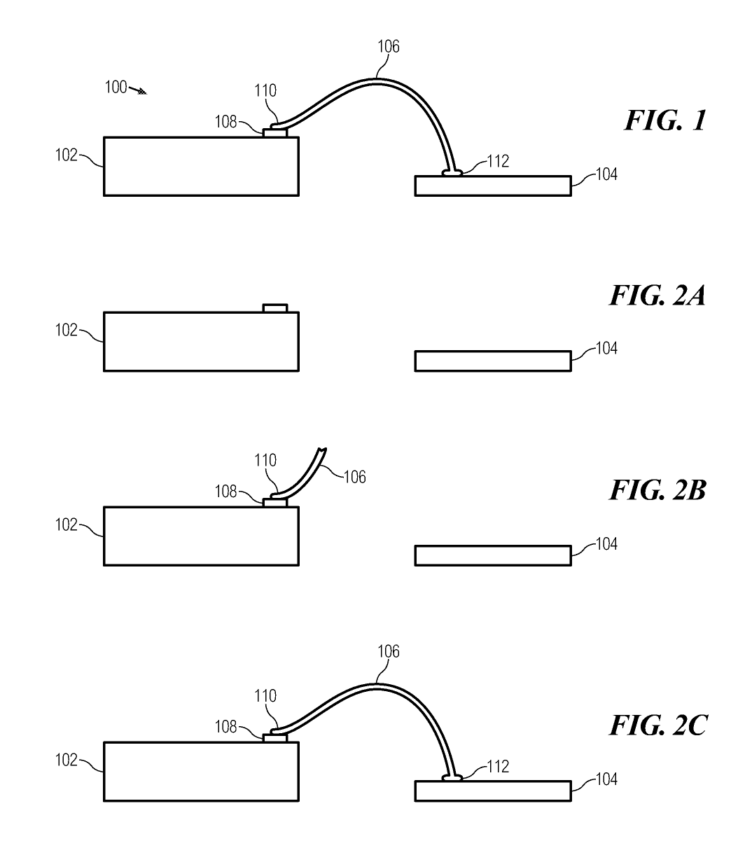

FIG. 1 illustrates a cross-sectional view of semiconductor package 100 in accordance with one embodiment. Semiconductor package 100 includes semiconductor chip 102, metal element 104 and wire bond 106. Chip 102 includes bond pad 108 that includes a copper layer (not illustrated). Wire bond 106 is wedge bonded to bond pad 108 at wedge bond 110 and ball bonded to metal element 104 at ball bond 112.

FIGS. 2A-2C illustrates cross-sectional views of a method of making semiconductor package 100. In FIG. 2A, chip 102 and metal element 104 are provided. In FIG. 2B, wire bond 106 is wedge bonded to bond pad 108 at wedge bond 110. In FIG. 2C, wire bond 106 is ball bonded to metal element 104 at ball bond 112.

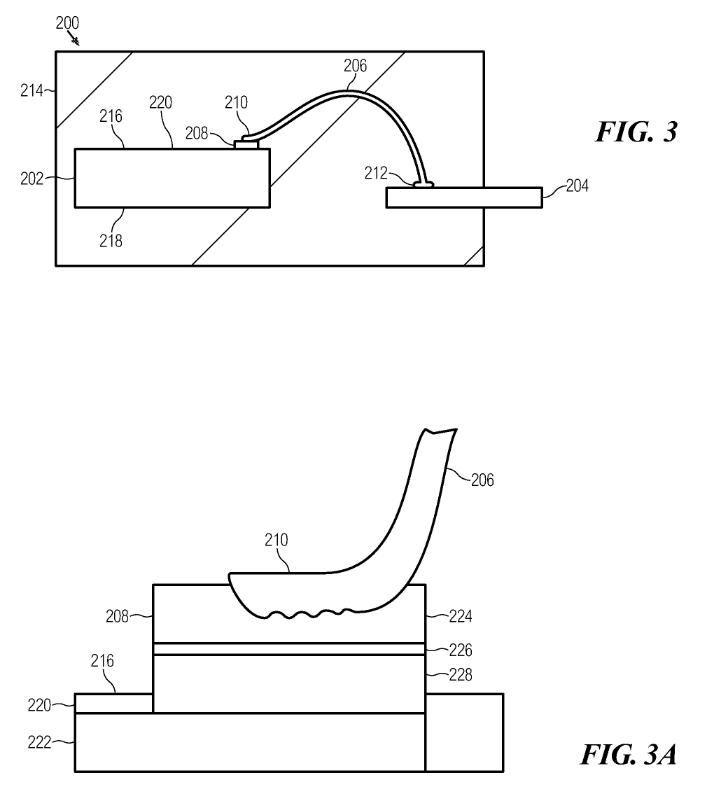

FIG. 3 illustrates a cross-sectional view of semiconductor package 200 in accordance with one embodiment. Semiconductor package 200 includes semiconductor chip 202, metal element 204, wire bond 206 and encapsulant 214, and chip 202 includes bond pad 208. Wire bond 206 is wedge bonded to bond pad 208 at wedge bond 210 and ball bonded to metal element 204 at ball bond 212.

Chip 202 includes opposing major surfaces 216 and 218. Chip 202 also includes bond pad 208 and passivation layer 220 at surface 216. Bond pad 208 protrudes from passivation layer 220 at surface 216.

Metal element 204 is a lead that is spaced from chip 202 and electrically connected to bond pad 208 by the wire bond 206, protrudes from encapsulant 214 and provides electrical conduction of current between bond pad 208 and external circuitry during operation of chip 202.

Encapsulant 214 contacts and protects chip 202 and wire bond 206.

FIG. 3A illustrates an enlarged cross-sectional view of bond pad 208 and wedge bond 210.

Chip 202 includes active metal layer 222 beneath surface 216. Active metal layer 222 is an interconnect line that electrically connects bond pad 208 with various transistors (not illustrated) within chip 202.

Bond pad 208 includes noble metal layer 224, adhesion layer 226 and copper layer 228. Noble metal layer 224 is a surface layer, adhesion metal layer 226 is buried beneath noble metal layer 224, and copper layer 228 is buried beneath noble metal layer 224 and adhesion metal layer 226. Thus, adhesion metal layer 226 contacts and is sandwiched between noble metal layer 224 and copper layer 228, copper layer 228 contacts and is sandwiched between adhesion metal layer 226 and active metal layer 222, and active metal layer 222 contacts and extends beneath copper layer 228. Thus, bond pad 208 excludes a ball bond. In addition, noble metal layer 224 prevents copper layer 228 from oxidizing.

Wire bond 206 can be various metals such as gold, silver, copper, gold-silver and copper-palladium, active metal layer 222 can be various metals such as aluminum and copper, noble metal layer 224 can be various noble metals such as palladium, gold and silver, and metal adhesion layer 226 can be various metals such as nickel, nickel-phosphorus and nickel-molybdenum. In one embodiment, wire bond 206 is gold, active metal layer 222 is aluminum, noble metal layer 224 is palladium, and metal adhesion layer 226 is nickel. In one embodiment, active metal layer 222 has a thickness of 2 microns, noble metal layer 224 has a thickness of 6 microns, adhesion metal layer 226 has a thickness of 1.2 microns, and copper layer 228 has a thickness of 6 microns.

Bond pad 208 is formed by an electroless plating operation. Initially, an opening is formed in passivation layer 220 that exposes the aluminum layer (active metal layer 222) using a photoresist layer as an etch mask. Thereafter, the structure is submerged in an electroless copper plating solution using the photoresist layer as a plating mask. As a result, the copper layer (copper layer 228) electrolessly plates on the aluminum layer. The electroless copper plating operation continues until the copper layer has the desired thickness. Thereafter, the structure is removed from the electroless copper plating solution and submerged in an electroless nickel plating solution using the photoresist layer as a plating mask. As a result, the nickel layer (metal adhesion layer 226) electrolessly plates on the copper layer. The electroless nickel plating operation continues until the nickel layer has the desired thickness. Thereafter, the structure is removed from the electroless nickel plating solution and submerged in an electroless palladium plating solution using the photoresist layer as a plating mask. As a result, the palladium layer (noble metal layer 224) electrolessly plates on the nickel layer. The electroless palladium plating operation continues until the palladium layer has the desired thickness. Thereafter, the structure is removed from the electroless palladium plating solution and rinsed in distilled water.

Wedge bond 210 extends into but not through noble metal layer 224 and is spaced from active metal layer 222, adhesion metal layer 226 and copper layer 228.

Wedge bond 210 is formed under substantial compressive force and vibration using ultrasonic bonding. As a result, wedge bond 210 creates cracks in noble metal layer 224 that propagate through adhesion metal layer 226 to copper layer 228. Furthermore, these cracks would propagate to active metal layer 222 and thus damage chip 202 in the absence of copper layer 228. Copper layer 228 absorbs stress created during the wedge bonding and does not crack due to its robust metallurgical properties, thereby protecting active metal layer 222 from cracks caused by wedge bond 210.

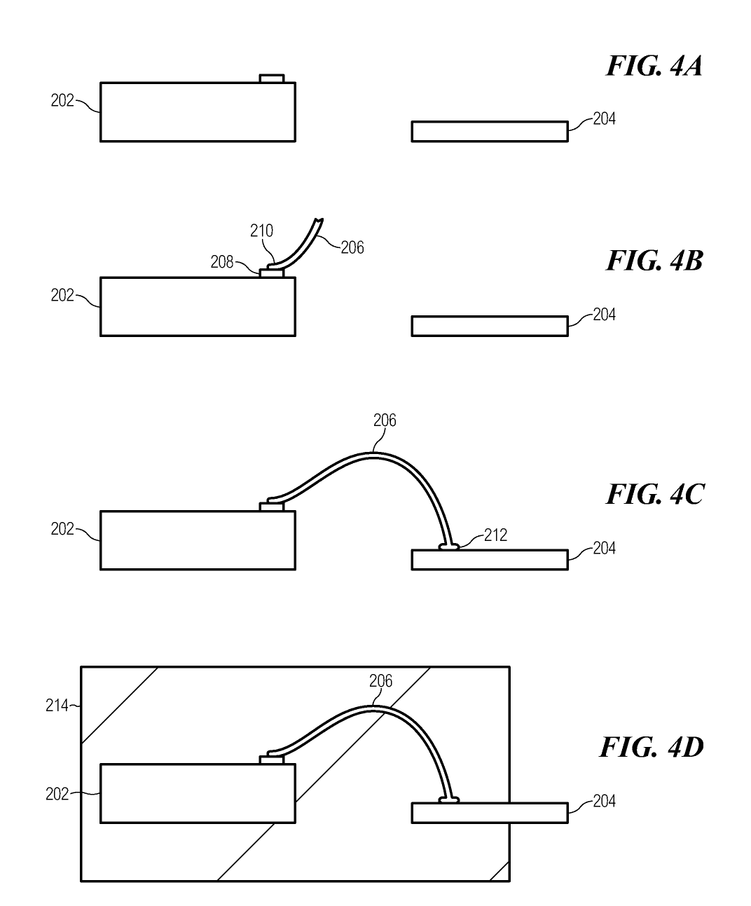

FIGS. 4A-4D illustrate cross-sectional views of a method of making semiconductor package 200. In FIG. 4A, chip 202 and metal element 204 are provided. In FIG. 4B, wire bond 206 is wedge bonded to bond pad 208 at wedge bond 210 using ultrasonic bonding. Wire bond 206 is wedge bonded to noble metal layer 224 without being wedge bonded to copper layer 228. In FIG. 4C, wire bond 206 is ball bonded to metal element 204 at ball bond 212 using thermosonic bonding. In FIG. 4D, encapsulant 214 is formed on chip 202, metal element 204 and wire bond 206, in one embodiment by transfer molding.

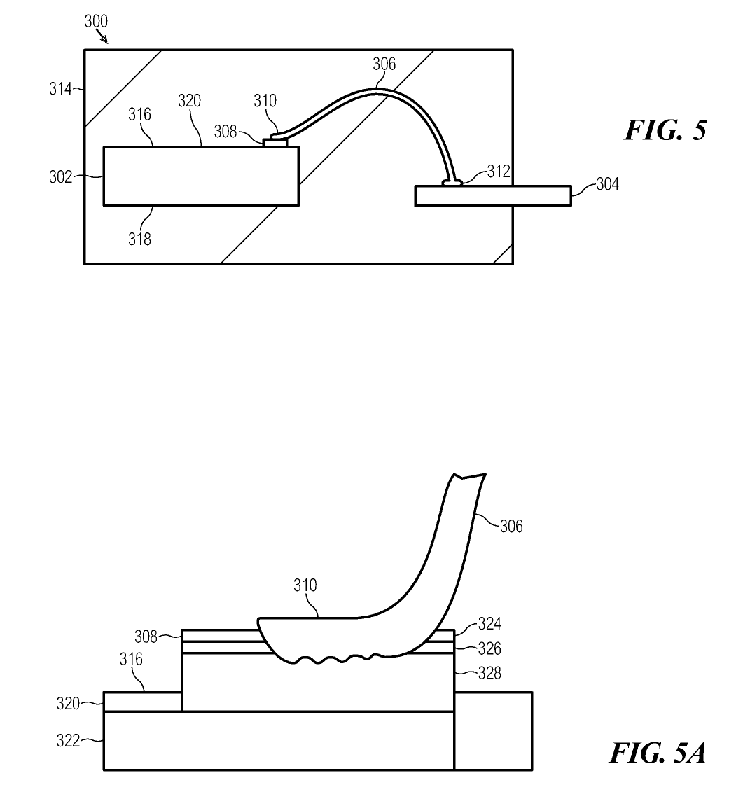

FIG. 5 illustrates a cross-sectional view of semiconductor package 300 in accordance with one embodiment. Semiconductor package 300 includes semiconductor chip 302, metal element 304, wire bond 306 and encapsulant 314, and chip 302 includes bond pad 308. Wire bond 306 is wedge bonded to bond pad 308 at wedge bond 310 and ball bonded to metal element 304 at ball bond 312.

Semiconductor package 300 is generally similar to semiconductor package 200, except that noble metal layer 324 and adhesion metal layer 326 are thinner than noble metal layer 224 and adhesion metal layer 224, and wedge bond 310 extends through noble metal layer 324 and adhesion metal layer 326 into copper layer 328.

FIG. 5A illustrates an enlarged cross-sectional view of bond pad 308 and wedge bond 310.

Chip 302 includes active metal layer 322. Bond pad 308 includes noble metal layer 324, adhesion layer 326 and copper layer 328.

Wire bond 306 can be various metals such as copper and copper-palladium, active metal layer 322 can be various metals such as aluminum and copper, noble metal layer 324 can be various noble metals such as palladium, gold and silver, and metal adhesion layer 326 can be various metals such as nickel, nickel-phosphorus and nickel-molybdenum. In one embodiment, wire bond 306 is copper, active metal layer 322 is aluminum, noble metal layer 324 is palladium, and metal adhesion layer 326 is nickel. In one embodiment, active metal layer 322 has a thickness of 2 microns, noble metal layer 324 has a thickness of 1 micron, adhesion metal layer 326 has a thickness of 0.5 microns, and copper layer 328 has a thickness of 6 microns.

Bond pad 308 is formed by an electroless plating operation in a manner similar to bond pad 208.

Wedge bond 310 extends through noble metal layer 324 and adhesion metal layer 326 into but not through copper layer 328 and is spaced from active metal layer 322.

Wedge bond 310 creates cracks in noble metal layer 324 and adhesion metal layer 326. Furthermore, these cracks would propagate to active metal layer 322 and thus damage chip 302 in the absence of copper layer 328. Advantageously, copper layer 328 absorbs stress created during the wedge bonding and does not crack due to its robust metallurgical properties, thereby protecting active metal layer 322 from cracks caused by wedge bond 310.

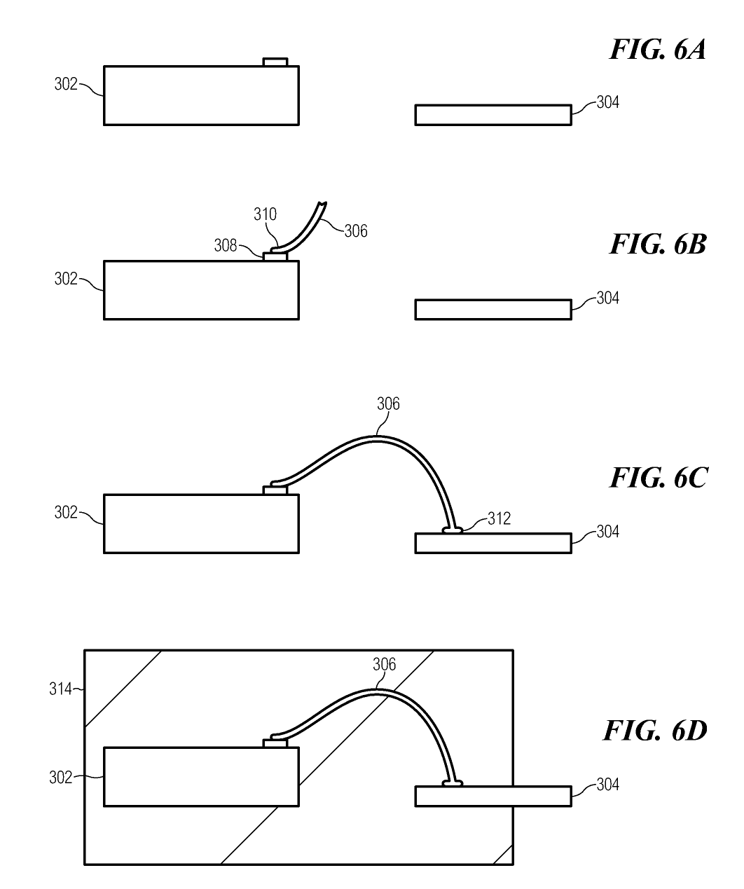

FIGS. 6A-6D illustrate a cross-sectional views of a method of making semiconductor package 300. In FIG. 6A, chip 302 and metal element 304 are provided. In FIG. 6B, wire bond 306 is wedge bonded to bond pad 308 at wedge bond 310 using ultrasonic bonding. Wire bond 306 is wedge bonded to noble metal layer 324, active metal layer 326 and copper layer 328. In FIG. 6C, wire bond 306 is ball bonded to metal element 304 at ball bond 312 using thermosonic bonding. In FIG. 6D, encapsulant 314 is formed on chip 302, metal element 304 and wire bond 306 by transfer molding.

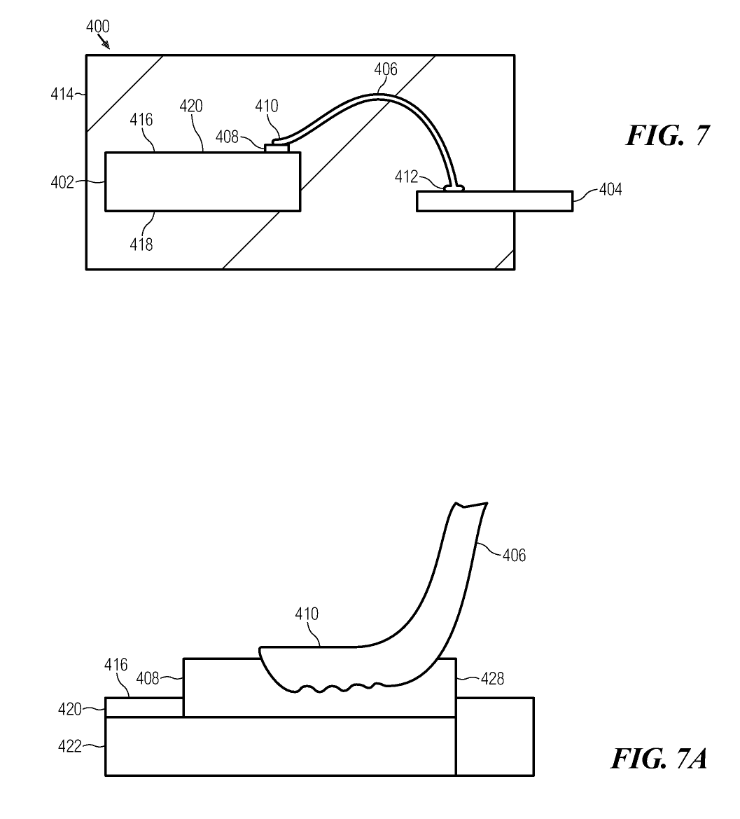

FIG. 7 illustrates a cross-sectional view of semiconductor package 400 in accordance with one embodiment. Semiconductor package 400 includes semiconductor chip 402, metal element 404, wire bond 406 and encapsulant 414, and chip 402 includes bond pad 408. Wire bond 406 is wedge bonded to bond pad 408 at wedge bond 410 and ball bonded to metal element 404 at ball bond 412.

Semiconductor package 400 is generally similar to semiconductor package 200, except that bond pad 408 is copper layer 428, and wedge bond 410 extends into copper layer 428.

FIG. 7A illustrates an enlarged cross-sectional view of bond pad 408 and wedge bond 410.

Chip 402 includes active metal layer 422. Bond pad 408 includes copper layer 428, which is a surface layer (rather than a buried layer).

Wire bond 406 can be various metals such as copper and copper-palladium, and active metal layer 422 can be various metals such as aluminum and copper. In one embodiment, wire bond 406 is copper, and active metal layer 422 is aluminum. In one embodiment, active metal layer 422 has a thickness of 2 microns, and copper layer 428 has a thickness of 6 microns.

Bond pad 408 is formed by an electroless plating operation in a manner similar to bond pad 208, except that the copper layer is electrolessly plated on the aluminum layer and the electroless nickel and palladium plating operations are omitted.

Wedge bond 410 extends into but not through copper layer 428 and is spaced from active metal layer 422.

Wedge bond 410 could create cracks that would propagate to active metal layer 422 and thus damage chip 402 in the absence of copper layer 428. Advantageously, copper layer 428 absorbs stress created during the wedge bonding and does not crack due to its robust metallurgical properties, thereby protecting active metal layer 422 from cracks caused by wedge bond 410.

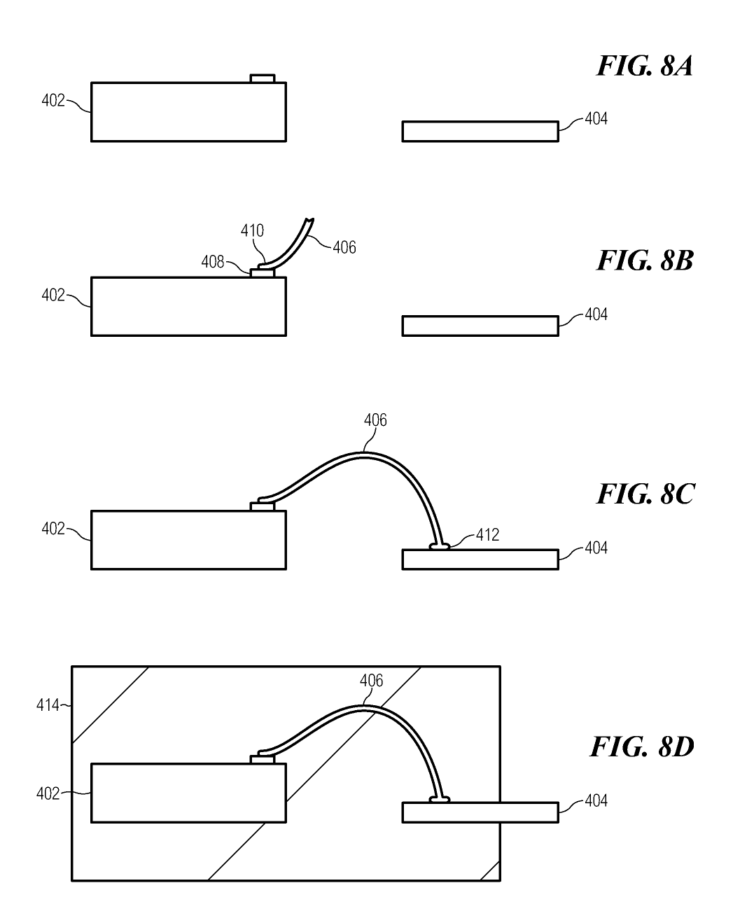

FIGS. 8A-8D illustrate a cross-sectional views of a method of making semiconductor package 400. In FIG. 8A, chip 402 and metal element 404 are provided. In FIG. 8B, wire bond 406 is wedge bonded to bond pad 408 at wedge bond 410 using ultrasonic bonding. Wire bond 406 is wedge bonded to copper layer 428. In FIG. 8C, wire bond 406 is ball bonded to metal element 404 at ball bond 412 using thermosonic bonding. In FIG. 8D, encapsulant 414 is formed on chip 402, metal element 404 and wire bond 406 by transfer molding.

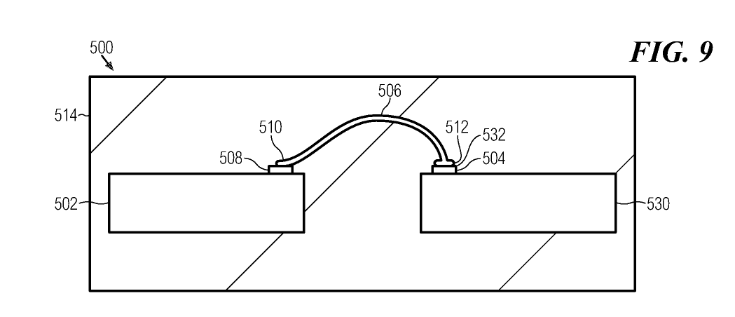

FIG. 9 illustrates a cross-sectional view of semiconductor package 500 in accordance with one embodiment. Semiconductor package 500 includes semiconductor chip 502, metal element 504, wire bond 506 and encapsulant 514, and chip 502 includes bond pad 508. Wire bond 506 is wedge bonded to bond pad 508 at wedge bond 510 and ball bonded to metal element 504 at ball bond 512.

Semiconductor package 500 is generally similar to semiconductor package 200, except that semiconductor package 500 includes semiconductor chip 530 with bond pad 532 and metal element 504 is bond pad 532. Wire bond 506 provides electrical conduction of current between chips 502 and 530 during operation of chips 502 and 530. Encapsulant 514 contacts and protects chips 502 and 530 and wire bond 506.

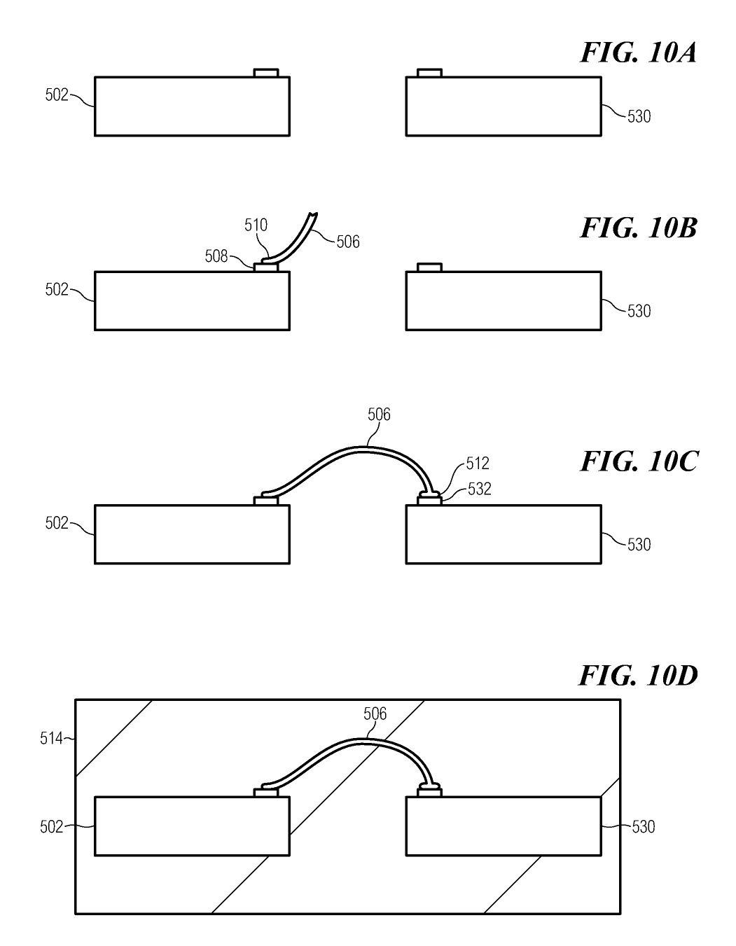

FIGS. 10A-10D illustrate a cross-sectional views of a method of making semiconductor package 500. In FIG. 10A, chips 502 and 530 are provided. In FIG. 10B, wire bond 506 is wedge bonded to bond pad 508 at wedge bond 510 using ultrasonic bonding. In FIG. 10C, wire bond 506 is ball bonded to bond pad 532 at ball bond 512 using thermosonic bonding. In FIG. 10D, encapsulant 514 is formed on chips 502 and 530 and wire bond 506 by transfer molding.

The above description and examples illustrate embodiments of the present invention, and it will be appreciated that various modifications and improvements can be made without departing from the scope of the present invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a semiconductor chip that includes a bond pad with a copper layer;
a metal element spaced from the chip; and
a wire bond wedge bonded to the bond pad and ball bonded to the metal element.

2. The semiconductor package of claim 1, wherein the bond pad includes a noble metal layer, the copper layer is buried beneath the noble metal layer, and the wedge bond extends into but not through the noble metal layer and is spaced from the copper layer.

3. The semiconductor package of claim 1, comprising wherein the bond pad includes a noble metal layer, the copper layer is buried beneath the noble metal layer, and the wedge bond extends through the noble layer metal into but not through the copper layer.

4. The semiconductor package of claim 1, comprising wherein the copper layer is a surface layer, and the wedge bond extends into but not through the copper layer.

5. The semiconductor package of claim 1, comprising wherein the bond pad excludes a ball bond.

6. A semiconductor package, comprising:
a semiconductor chip that includes a bond pad with a copper layer and without a ball bond;
a metal element that is spaced from the chip; and
a wire bond that includes a wedge bond and a ball bond, wherein the wire bond is welded at the wedge bond to the bond pad and is welded at the ball bond to the metal element, thereby electrically connecting the bond pad and the metal element.

7. The semiconductor package of claim 6, comprising wherein the chip includes an active metal layer that contacts and extends beneath the copper layer, the bond pad includes a noble metal layer that is a surface layer, the copper layer is buried beneath the noble metal layer and is sandwiched between the noble metal layer and the active metal layer, and the wedge bond extends into but not through the noble metal layer and is spaced from the copper layer and the active metal layer.

8. The semiconductor package of claim 6, comprising wherein the chip includes an active metal layer that contacts and extends beneath the copper layer, the copper layer is a surface layer, and the wedge bond extends into but not through the copper layer and is spaced from the active metal layer.

9. The semiconductor package of claim 6, comprising wherein the metal element is a lead that is electrically connected to the bond pad by the wire bond and provides electrical conduction of current between the bond pad and external circuitry during operation of the chip.

10. The semiconductor package of claim 6, comprising wherein the metal element is a bond pad of another chip and the wire bond provides electrical conduction of current between the chips during operation of the chips.

11. A semiconductor package, comprising:
a semiconductor chip that includes a bond pad that includes a copper layer;
a metal element that is spaced from the chip; and
wire bond means that is welded at a wedge bond to the bond pad and is welded at a ball bond to the metal element, thereby electrically connecting the bond pad and the metal element.

12. The semiconductor package of claim 11, comprising wherein the chip includes an active metal layer that contacts and extends beneath the copper layer, the bond pad includes a noble metal layer that is a surface layer, the copper layer is buried beneath the noble metal layer and is sandwiched between the noble metal layer and the active metal layer, and the wedge bond extends into but not through the noble metal layer and is spaced from the copper layer and the active metal layer.

13. The semiconductor package of claim 11, comprising wherein the chip includes an active metal layer that contacts and extends beneath the copper layer, the copper layer is a surface layer, and the wedge bond extends into but not through the copper layer and is spaced from the active metal layer.

14. The semiconductor package of claim 11, comprising wherein the metal element is a lead that is electrically connected to the bond pad by the wire bond and provides electrical conduction of current between the bond pad and external circuitry during operation of the chip.

15. The semiconductor package of claim 11, comprising wherein the metal element is a bond pad of another chip and the wire bond provides electrical conduction of current between the chips during operation of the chips.

16. A method of manufacturing a semiconductor package, comprising:
providing a semiconductor chip, wherein the chip includes a bond pad that includes a copper layer;
providing a metal element that is spaced from the chip;
wedge bonding a wire bond to the bond pad; and
ball bonding the wire bond to the metal element.

17. The method of claim 16, comprising wedge bonding the wire bond to a noble metal layer of the bond pad without wedge bonding the wedge bond to the copper layer.

18. The method of claim 16, comprising wedge bonding the wire bond to the copper layer.

19. The method of claim 16, comprising wherein the metal element is a lead electrically connected to the bond pad by the wire bond and the lead provides electrical conduction of current between the bond pad and external circuitry during operation of the chip.

20. The method of claim 16, comprising wherein the metal element is a bond pad of another chip and the wire bond provides electrical conduction of current between the chips during operation of the chips.

21. A method of manufacturing a semiconductor package, comprising:
providing a semiconductor chip, wherein the chip includes a bond pad and the bond pad includes a copper layer and excludes a ball bond;
providing a metal element that is spaced from the chip;
wedge bonding a wire bond to the bond pad using ultrasonic bonding;
ball bonding the wire bond to the metal element using thermosonic bonding; and
providing an encapsulant that contacts and protects the chip and the wire bond.

22. The method of claim 21, comprising wedge bonding the wire bond to a noble metal layer of the bond pad without wedge bonding the wire bond to the copper layer.

23. The method of claim 21, comprising wedge bonding the wire bond to the copper layer.

24. The method of claim 21 comprising wherein the metal element is a lead that is electrically connected to the bond pad by the wire bond and protrudes from the encapsulant and provides electrical conduction of current between the bond pad and external circuitry during operation of the chip.

25. The method of claim 21, comprising wherein the metal element is a second bond pad of a second chip, the second bond pad excludes a wedge bond, the encapsulant contacts and protects the second chip and the wire bond provides electrical conduction of current between the chips during operation of the chips.
